(19) United States
(12) Patent Application Publication
(10) Pub. No.: US 2008/0236746 A1
(43) Pub. Date: Oct. 2, 2008

(54) SUBSTRATE PROCESSING APPARATUS AND SUBSTRATE MOUNTING STAGE ON WHICH FOCUS RING IS MOUNTED

(75) Inventors: Jun OYABU, Nirasaki-shi (JP); Masaaki MIYAGAWA, Nirasaki-shi (JP)

Correspondence Address: OBLON, SPIVAK, MCCLELLAND MAIER & NEUSTADT, P.C., 1940 DUKE STREET, ALEXANDRIA, VA, 22314, US

(73) Assignee: TOKYO ELECTRON LIMITED, Tokyo (JP)

(21) Appl. No.: 12/057,827

(22) Filed: Mar. 28, 2008

Related U.S. Application Data
(60) Provisional application No. 60/938,734, filed on May 18, 2007.

(30) Foreign Application Priority Data
Mar. 29, 2007 (JP) 2007-089802

(51) Int. Cl. H01L 21/306

(52) U.S. Cl. 156/345.23

(57) ABSTRACT

A substrate processing apparatus that can prevent a heat transfer sheet from becoming attached to a focus ring mounting surface of a substrate mounting stage. The substrate mounting stage is disposed in a housing chamber of the substrate processing apparatus, and a substrate is mounted on the substrate mounting stage. A focus ring that surrounds a peripheral portion of the mounted substrate is mounted on the focus ring mounting surface. The heat transfer sheet is interposed between the focus ring and the focus ring mounting surface, and a fluorine coating is formed on the focus ring mounting surface.

### BACKGROUND OF THE INVENTION

1. Field of the Invention

The present invention relates to a substrate processing apparatus and a substrate mounting stage on which a focus ring is mounted, and in particular to a substrate mounting stage on which a focus ring is mounted with a heat transfer sheet interposed therebetween.

2. Description of the Related Art

In the case of carrying out plasma processing such as etching processing on a wafer as a substrate, the width and depth of trenches formed on a surface of the wafer through etching are affected by the temperature of the wafer, and hence the temperature of the entire surface of the wafer is required to be maintained uniform during the etching processing.

Substrate processing apparatuses that carry out the etching processing on a wafer has a chamber that houses the wafer and can be evacuated, and a substrate mounting stage (hereinafter referred to as the “susceptor”) on which the wafer is mounted during the etching processing. In the evacuated chamber, plasma is produced, and the wafer is etched by the plasma. The susceptor has a temperature controlling mechanism and controls the temperature of the wafer on which the etching processing is carried out. When the wafer is subjected to the etching processing, the temperature of the wafer rises because it is exposed to heat from the plasma, and thus the temperature controlling mechanism of the susceptor cools the wafer so as to maintain the temperature of the wafer constant.

Moreover, an annular focus ring made of, for example, silicon is mounted on the susceptor such as to surround a peripheral portion of the wafer. The focus ring focuses the plasma in the chamber onto the wafer. The focus ring is also exposed to heat from the plasma during the etching processing, and as a result, the temperature of the focus ring rises to, for example, about 300° C. to 400° C.

During the etching processing, because the peripheral portion of the wafer is affected by heat radiated from the focus ring, it is difficult to maintain the temperature of the entire surface of the wafer uniform. Moreover, because the focus ring is merely mounted on the susceptor, the efficiency of heat transfer between the focus ring and the susceptor is low. As a result, heat accumulates in the focus ring, and the temperature of the focus ring cannot be maintained constant, and it is thus difficult to carry out the etching processing uniformly on a plurality of wafers in the same lot.

In view of the foregoing, it is necessary to actively control the temperature of the focus ring. Accordingly, the present applicant has recently developed a method of improving the efficiency of heat transfer between the focus ring and the susceptor and actively controlling the temperature of the focus ring using the temperature controlling mechanism of the susceptor (see, for example, Japanese Laid-Open Patent Publication (Kokai) No. 2002-16126). In this method, a heat transfer sheet is provided between the focus ring and the susceptor so as to improve the efficiency of heat transfer between the focus ring and the susceptor.

However, the heat transfer sheet is comprised of a heat-resistant elastic member such as conductive silicon rubber and has flexibility, and hence the transfer sheet becomes closely attached to the focus ring and a focus ring mounting surface of the susceptor. At this time, if the heat transfer sheet becomes closely attached to the focus ring mounting surface of the susceptor, then the following problems will arise:
1. If the heat transfer sheet becomes attached to the focus ring as well, it becomes difficult to remove the focus ring from the susceptor.
2. When the focus ring is to be removed from the susceptor, the heat transfer sheet is broken and becomes attached as foreign matter to the interior of the chamber.
3. After the focus ring is removed from the susceptor, the heat transfer sheet remains in the susceptor, but it is difficult to remove the heat transfer sheet because it is difficult to take out the susceptor from the chamber.

### SUMMARY OF THE INVENTION

The present invention provides a substrate processing apparatus and a substrate mounting stage on which a focus ring is mounted, which can prevent a heat transfer sheet from becoming attached to a focus ring mounting surface of the substrate mounting stage.

Accordingly, in a first aspect of the present invention, there is provided a substrate processing apparatus comprising a housing chamber that houses a substrate, a substrate mounting stage that is disposed in the housing chamber and on which the substrate is mounted, and a focus ring that surrounds a peripheral portion of the mounted substrate, wherein the substrate mounting stage has a focus ring mounting surface on which the focus ring is mounted, a heat transfer sheet is interposed between the focus ring and the focus ring mounting surface, and a fluorine coating is formed on the focus ring mounting surface.

According to the first aspect of the present invention, the fluorine coating is formed on the focus ring mounting surface of the substrate mounting stage. If the heat transfer sheet becomes closely attached to a rough surface, part of the heat transfer sheet enters minute depressions on the rough surface when viewed microscopically, and as a result, the heat transfer sheet becomes attached to the rough surface. The fluorine coating, however, fills in minute depressions on the focus ring mounting surface. Moreover, because the fluorine coating has a very tight molecular bond structure, molecules constituting the heat transfer sheet cannot easily enter gaps between molecules constituting the fluorine coating. As a result, the heat transfer sheet can be prevented from becoming attached to the focus ring mounting surface.

The first aspect of the present invention can provide a substrate processing apparatus, wherein a thickness of the fluorine coating is not less than 3 μm and not more than 100 μm.

According to the first aspect of the present invention, the thickness of the fluorine coating is not less than 3 μm and not more than 100 μm. The arithmetic mean deviation of the profile (Ra) of the focus ring mounting surface is 1.6 μm, and hence the fluorine coating can reliably fill in the minute depressions on the focus ring mounting surface. Moreover, insofar as the thickness of the fluorine coating is not more than 100 μm, the thermal resistance of the fluorine coating can be so small as to be negligible, and hence heat can be reliably transferred from the focus ring to the substrate mounting stage via the heat transfer sheet.

Accordingly, in a second aspect of the present invention, there is provided a substrate processing apparatus comprising a housing chamber that houses a substrate, a substrate mounting stage that is disposed in the housing chamber and on which the substrate is mounted, and an annular member, wherein the substrate mounting stage has a focus ring mounting surface on which the focus ring is mounted, a heat transfer sheet is interposed between the focus ring and the focus ring mounting surface, and the annular member is interposed between the heat transfer sheet and the focus ring mounting surface and disposed concentrically with the focus ring and has a heat transfer sheet contact surface that contacts the heat transfer sheet, and a fluorine coating is formed on the heat transfer sheet contact surface.

According to the second aspect of the present invention, because the annular member is interposed between the heat transfer sheet and the focus ring mounting surface, the heat transfer sheet can be prevented from becoming attached to the focus ring mounting surface of the substrate mounting stage. Moreover, because the fluorine coating is formed on the heat transfer sheet contact surface of the annular member, the fluorine coating, however, fills in minute depressions on the heat transfer sheet contact surface. Furthermore, because the fluorine coating has a very tight molecular bond structure, molecules constituting the heat transfer sheet cannot easily enter gaps between molecules constituting the fluorine coating. As a result, the heat transfer sheet can be prevented from becoming attached to the heat transfer sheet contact surface. Moreover, even if the flouring coating becomes damaged, a new fluorine coating can be provided by replacing the annular member, and hence the function of preventing the heat transfer sheet from becoming attached to the focus ring mounting surface can be easily maintained.

Accordingly, in a third aspect of the present invention, there is provided a substrate mounting stage on which a substrate and a focus ring are mounted in a substrate processing apparatus that has a housing chamber that houses the substrate, and the focus ring that surrounds a peripheral portion of the substrate housed in the housing chamber, comprising a focus ring mounting surface on which the focus ring is mounted, wherein a heat transfer sheet is interposed between the focus ring and the focus ring mounting surface, and a fluorine coating is formed on the focus ring mounting surface.

Accordingly, in a fourth aspect of the present invention, there is provided a substrate mounting stage on which a substrate and a focus ring are mounted in a substrate processing apparatus that has a housing chamber that houses the substrate, and the focus ring that surrounds a peripheral portion of the substrate housed in the housing chamber, comprising a focus ring mounting surface on which the focus ring is mounted, wherein a heat transfer sheet is interposed between the focus ring and the focus ring mounting surface, an annular member disposed concentrically with the focus ring is interposed between the heat transfer sheet and the focus ring mounting surface, and the annular member has a heat transfer sheet contact surface that contacts the heat transfer sheet, and a fluorine coating is formed on the heat transfer sheet contact surface.

The features and advantages of the invention will become more apparent from the following detailed description taken in conjunction with the accompanying drawings.

### BRIEF DESCRIPTION OF THE DRAWINGS

FIG. 1 is a sectional view schematically showing the construction of a substrate processing apparatus according to a first embodiment of the present invention;

FIG. 2 is an enlarged sectional view schematically showing the constructions of a focus ring, a heat transfer sheet, and a focus ring mounting surface and their vicinity in the substrate processing apparatus according to the first embodiment;

FIG. 3 is an enlarged sectional view schematically showing the constructions of a focus ring, a heat transfer sheet, and a focus ring mounting surface and their vicinity in the substrate processing apparatus according to a second embodiment of the present invention;

FIG. 4 is a view showing how a heat transfer sheet is disposed in an example 1 of the present invention;

FIGS. 5A to 5D are graphs showing the results of etching processing on an oxide film and a BARC film in an example 2 and a comparative example 2 of the present invention, in which FIG. 5A is a graph showing the distribution of etch rate in the etching processing on the oxide film in the example 2, FIG. 5B is a graph showing the distribution of etch rate in the etching processing on the BARC film in the example 2, FIG. 5C is a graph showing the distribution of etch rate in the etching processing on the oxide film in the comparative example 2, and FIG. 5D is a graph showing the distribution of etch rate in the etching processing on the BARC film in the comparative example 2; and

FIGS. 6A and 6B are graphs showing the results of etching processing on an oxide film and a BARC film in a comparative example 3 of the present invention, in which FIG. 6A is a graph showing the distribution of etch rate in the etching processing on the oxide film in the comparative example 3, and FIG. 6B is a graph showing the distribution of etch rate in the etching processing on the BARC film in the comparative example 3.

### DETAILED DESCRIPTION OF THE PREFERRED EMBODIMENTS

The present invention will now be described in detail with reference to the drawings showing a preferred embodiment thereof.

First, a description will be given of a substrate processing apparatus according to a first embodiment of the present invention.

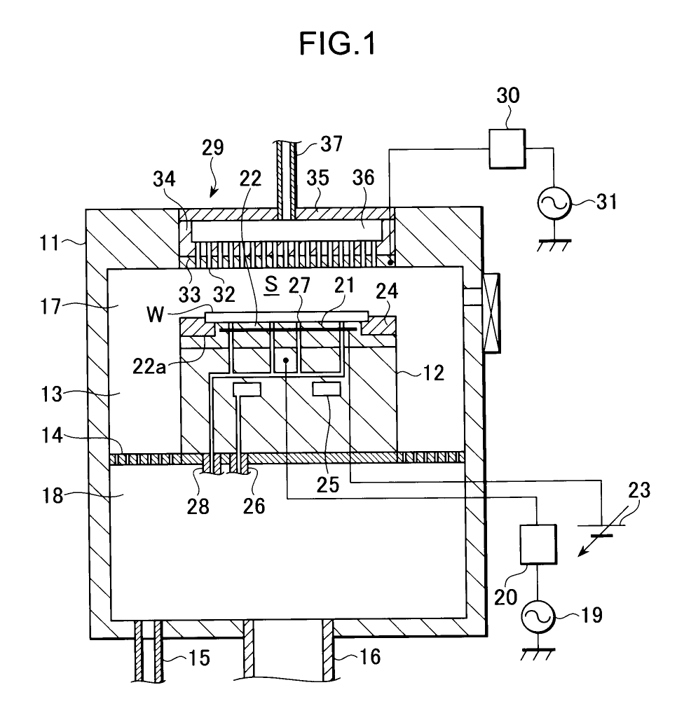

FIG. 1 is a sectional view schematically showing the construction of the substrate processing apparatus according to the present embodiment. The substrate processing apparatus is constructed such as to carry out etching processing on a semiconductor wafer as a substrate.

As shown in FIG. 1, the substrate processing apparatus 10 has a chamber 11 (housing chamber) in which a semiconductor wafer (hereinafter referred to merely as a “wafer”) W having a diameter of, for example, 300 mm is housed. A cylindrical susceptor 12 (substrate mounting stage) is disposed in the chamber 11 as a stage on which the wafer W is mounted. In the substrate processing apparatus 10, a side exhaust path 13 that acts as a flow path through which gas above the susceptor 12 is exhausted out of the chamber 11 is formed between an inner side wall of the chamber 11 and the side face of the susceptor 12. An exhaust plate 14 is disposed part way along the side exhaust path 13.

The exhaust plate 14 is a plate-like member having a number of holes therein and acts as a partition plate that partitions the chamber 11 into an upper portion and a lower portion. In the upper portion (hereinafter referred to as “the reaction chamber”) 17 of the chamber 11 partitioned by the exhaust plate 14, plasma is produced as will be described later. In the lower portion (hereinafter referred to as “the exhaust chamber (manifold)”) 18 of the chamber 11, a roughing exhaust pipe 15 and a main exhaust pipe 16 which exhaust gas out of the chamber 11 are opened. The roughing exhaust pipe 15 has a DP (dry pump) (not shown) connected thereto, and the main exhaust pipe 16 has a TMP (turbo-molecular pump) (not shown) connected thereto. The exhaust plate 14 captures or reflects ions and radicals produced in a processing space S between the susceptor 12 and a shower head 29, described later, in the reaction chamber 17 to prevent the leakage of ions and radicals therefrom into the manifold 18.

The roughing exhaust pipe 15 and the main exhaust pipe 16 exhaust gas in the reaction chamber 17 out of the chamber 11 via the manifold 18. Specifically, the roughing exhaust pipe 15 reduces the pressure in the chamber 11 from atmospheric pressure down to a low vacuum state, and the main exhaust pipe 16 is operated in collaboration with the roughing exhaust pipe 15 to reduce the pressure in the chamber 11 down to a high vacuum state (e.g. a pressure of not more than 133 Pa (1 Torr)), which is at a lower pressure than the low vacuum state.

A lower radio frequency power source 19 is connected to the susceptor 12 via a lower matcher 20. The lower radio frequency power source 19 applies predetermined radio frequency electrical power to the susceptor 12. The susceptor 12 thus acts as a lower electrode. The lower matcher 20 reduces reflection of the radio frequency electrical power from the susceptor 12 so as to maximize the efficiency of the supply of the radio frequency electrical power into the susceptor 12.

An electrostatic chuck 22 having an electrostatic electrode plate 21 therein is provided in an upper portion of the susceptor 12. The electrostatic chuck 22 is formed by overlaying an upper disk-shaped member having a given diameter on a lower disk-shaped member having a larger diameter than the diameter of the upper disk-shaped member. The electrostatic chuck 22 is made of aluminum, and for example, ceramic is thermally sprayed on the upper surface of the upper disk-shaped member. When a wafer W is mounted on the susceptor 12, the wafer W is disposed on the upper disk-shaped member of the electrostatic chuck 22.

A DC power source 23 is electrically connected to the electrostatic electrode plate 21 of the electrostatic chuck 22. Upon a positive DC voltage being applied to the electrostatic electrode plate 21, a negative potential is produced on a surface of the wafer W which faces the electrostatic chuck 22 (hereinafter referred to as “the rear surface of the wafer W”). A potential difference thus arises between the electrostatic electrode plate 21 and the rear surface of the wafer W, and hence the wafer W is attracted to and held on the upper disk-shaped member of the electrostatic chuck 22 through a Coulomb force or a Johnsen-Rahbek force due to the potential difference.

An annular focus ring 24 is disposed in a portion 22a (hereinafter referred to as “the focus ring mounting surface”) of the upper surface of the lower disk-shaped member of the electrostatic chuck 22 on which the upper disk-shaped member is not overlaid. Here, the electrostatic chuck 22 constitutes a part of the mounting stage, and hence it can also be said that the susceptor 12 has the focus ring mounting surface 22a.

The focus ring 24 is made of a conductive material, for example silicon, and surrounds the wafer W attracted to and held on the upper disk-shaped member of the electrostatic chuck 22. Moreover, the focus ring 24 focuses plasma in the processing space S toward a front surface of the wafer W, thus improving the efficiency of the etching processing.

An annular coolant chamber 25 that extends, for example, in a circumferential direction of the susceptor 12 is provided inside the susceptor 12. A coolant, for example cooling water or a Galden (registered trademark) fluid, at a low temperature is circulated through the coolant chamber 25 via coolant piping 26 from a chiller unit (not shown). The susceptor 12 cooled by the low-temperature coolant cools the wafer W and the focus ring 24 via the electrostatic chuck 22. The temperatures of the wafer W and the focus ring 24 are mainly controlled through the temperature and flow rate of the coolant circulated through the coolant chamber 25.

A plurality of heat transfer gas supply holes 27 are opened to a portion of the upper disk-shaped member of the electrostatic chuck 22 on which the wafer W is attracted and held (hereinafter referred to as the “attracting surface”). The heat transfer gas supply holes 27 are connected to a heat transfer gas supply unit (not shown) by a heat transfer gas supply line 28. The heat transfer gas supply unit supplies helium (He) gas as a heat transfer gas via the heat transfer gas supply holes 27 into a gap between the attracting surface and the rear surface of the wafer W. The helium gas supplied into the gap between the attracting surface and the rear surface of the wafer W effectively transfers heat from the wafer W to the electrostatic chuck 22.

The shower head 29 is disposed in a ceiling portion of the chamber 11 such as to face the susceptor 12. An upper radio frequency power source 31 is connected to the shower head 29 via an upper matcher 30 and applies predetermined radio frequency electrical power to the shower head 29. The shower head 29 thus acts as an upper electrode. The upper matcher 30 has a similar function to the lower matcher 20 described above.

The shower head 29 is comprised of a ceiling electrode plate 33 having a number of gas holes 32 therein, a cooling plate 34 from which the ceiling electrode plate 33 is detachably suspended, and a cover 35 that covers the cooling plate 34. A buffer chamber 36 is provided inside the shower head 29, and a processing gas introducing pipe 37 is connected to the buffer chamber 36. The shower head 29 supplies a processing gas supplied into the buffer chamber 36 from the processing gas introducing pipe 37 into the processing space S via the gas holes 32.

In the substrate processing apparatus 10, radio frequency electrical power is applied to the susceptor 12 and the shower head 29, and the radio frequency electrical power is applied to the processing space S. As a result, in the processing space S, the processing gas supplied from the shower head 29 is turned into high-density plasma so as to produce ions and radicals. The wafer W is subjected to the etching processing by the ions and radicals.

Operation of the component elements of the substrate processing apparatus 10 described above is controlled in accordance with a program for the etching processing by a CPU of a control unit (not shown) of the substrate processing apparatus 10.

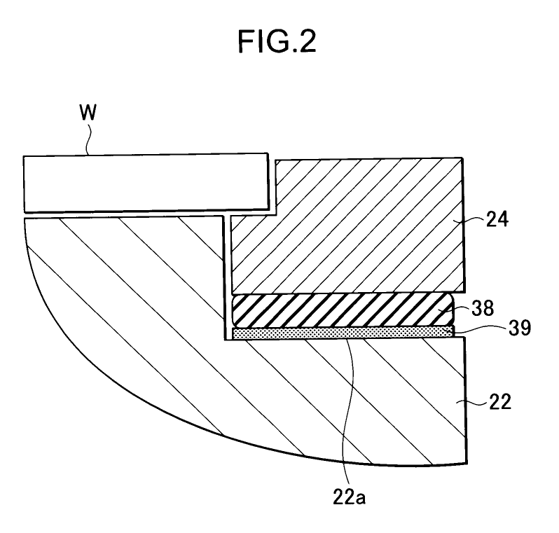

In the substrate processing apparatus 10 described above, an annular heat transfer sheet 38 is interposed between the focus ring 24 and the focus ring mounting surface 22a of the electrostatic chuck 22 as shown in FIG. 2. The heat transfer sheet 38 is disposed concentrically with the focus ring 24. Here, because the electrostatic chuck 22 is cooled by the susceptor 12, the electrostatic chuck 22 is held at a lower temperature than the temperature of the focus ring 24 during the etching processing. At this time, the heat transfer sheet 38 transfers heat of the focus ring 24 to the electrostatic chuck 22. Moreover, because the temperature of the focus ring 24 rises to nearly 200° C. even though it is cooled by the electrostatic chuck 22, the heat transfer sheet 38 has to be heat-resistant so that it can maintain its form at high temperature. It is thus preferred that the heat transfer sheet 38 is made of conductive silicon rubber.

The focus ring mounting surface 22a is subjected to finish processing in consideration of heat transfer, but the arithmetic mean deviation of the profile Ra of the focus ring mounting surface 22a is usually 1.6 μm due to a porous layer of the sprayed ceramic. There are thus minute projections and depressions on the focus ring mounting surface 22a when viewed microscopically. When the heat transfer sheet 38 is made to directly contact the focus ring mounting surface 22a, part of the heat transfer sheet 38 enters the minute depressions when viewed microscopically, and as a result, the heat transfer sheet 38 becomes attached to the focus ring mounting surface 22a. If the heat transfer sheet 38 becomes attached to the focus ring mounting surface 22a, the above described problems will arise. To cope with this, in the present embodiment, a fluorine coating 39 is formed on the focus ring mounting surface 22a. The thickness of the fluorine coating 39 is set to be not less than 3 μm in consideration of the surface roughness, in particular the maximum height of the profile (Ry) of the focus ring mounting surface 22a, and set to be not more than 100 μm so that the fluorine coating 39 does not act as a thermal resistance. It is preferred that the thickness of the fluorine coating 39 is small from the standpoint of suppressing thermal resistance.

According to the substrate processing apparatus 10 of the present embodiment, the fluorine coating 39 is formed on the focus ring mounting surface 22a. The fluorine coating 39 fills in the minute depressions on the focus ring mounting surface 22a. This prevents part of the heat transfer sheet 38 from entering the minute depressions on the focus ring mounting surface 22a when viewed microscopically. Moreover, in the present embodiment, the heat transfer sheet 38 directly contacts the fluorine coating 39, but because the fluorine coating 39 has a very tight molecular bond structure, molecules (silicon rubber molecules) constituting the heat transfer sheet 38 cannot easily enter gaps between molecules constituting the fluorine coating 39. As a result, the heat transfer sheet 38 can be prevented from becoming attached to the focus ring mounting surface 22a.

Further, because part of the heat transfer sheet 38 does not enter the minute depressions on the focus ring mounting surface 22a, the focus ring mounting surface 22a never becomes dirty, and hence the susceptor 12 never becomes ugly.

In the substrate processing apparatus 10 described above, the thickness of the fluorine coating 39 is not less than 3 μm and not more than 100 μm. Because the arithmetic mean deviation of the profile Ra of the focus ring mounting surface 22a is 1.6 μm, the fluorine coating 39 having a thickness of not less than 3 μm, which is approximately twice Ra, can reliably fill in the minute depressions on the focus ring mounting surface 22a. Moreover, if the thickness of the fluorine coating 39 is not more than 100 μm, the thermal resistance of the fluorine coating 39 can be made so small as to be negligible, and hence heat can be reliably transferred from the focus ring 24 to the electrostatic chuck 22 via the heat transfer sheet 38.

Moreover, in the substrate processing apparatus 10 described above, because no fluorine coating is formed on the surface of the focus ring 24 which contacts the heat transfer sheet 38, and the heat transfer sheet 38 directly contacts the focus ring 24, the heat transfer sheet 38 becomes closely attached to the focus ring 24. As a result, when the focus ring 24 is to be removed from the susceptor 12 (electrostatic chuck 22), the heat transfer sheet 38 can be removed while being kept attached to the focus ring 24.

A description will be given of a substrate processing apparatus according to a second embodiment of the present invention.

The present embodiment is basically the same as the first embodiment described above in terms of construction and operation, differing from the first embodiment in that a ring spacer is interposed between the heat transfer sheet and the focus ring mounting surface. Features of the construction and operation that are the same as in the first embodiment will thus not be described, only features that are different from those of the first embodiment being described below.

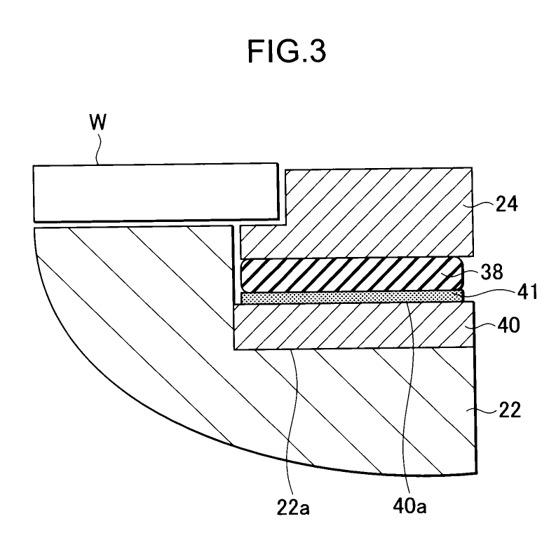

FIG. 3 is an enlarged sectional view schematically showing the constructions of a focus ring, a heat transfer sheet, and a focus ring mounting surface and their vicinity in the substrate processing apparatus according to the present embodiment.

As shown in FIG. 3, in the substrate processing apparatus 42, the annular heat transfer sheet 38 is interposed between the focus ring 24 and the focus ring mounting surface 22a of the electrostatic chuck 22, and further, an annular ring spacer 40 (annular member) is interposed between the heat transfer sheet 38 and the focus ring mounting surface 22a. The ring spacer 40 is made of, for example, aluminum and disposed concentrically with the focus ring 24 and the heat transfer sheet 38. That is, the heat transfer sheet 38 contacts the ring spacer 40. The heat transfer sheet 38 does not directly contact the focus ring mounting surface 22a due to the presence of the ring spacer 40.

A contact surface (hereinafter referred to as the “heat transfer sheet contact surface”) 40a of the ring spacer 40 which contacts the heat transfer sheet 38 is subjected to finish processing in consideration of heat transfer, but the arithmetic mean deviation of the profile Ra of the heat transfer sheet contact surface 40a is usually 3.2 μm, and there are minute projections and depressions on the heat transfer sheet contact surface 40a as well. Accordingly, in the present embodiment, a fluorine coating 41 is formed on the heat transfer sheet contact surface 40a. The thickness of the fluorine coating 41 is set to be not less than 6 μm in consideration of the surface roughness, in particular the maximum height of the profile (Ry) of the heat transfer sheet contact surface 40a.

According to the substrate processing apparatus 42 of the present embodiment, because the ring spacer 40 is interposed between the heat transfer sheet 38 and the focus ring mounting surface 22a, the heat transfer sheet 38 can be prevented from becoming attached to the focus ring mounting surface 22a. Moreover, because the fluorine coating 41 is formed on the heat transfer sheet contact surface 40a of the ring spacer 40, the fluorine coating 41 fills in the minute depressions on the heat transfer sheet contact surface 40a. Further, molecules constituting the heat transfer sheet 38 cannot easily enter gaps between molecules constituting the fluorine coating 41. As a result, the heat transfer sheet 38 can be prevented from becoming attached to the heat transfer sheet contact surface 40a. Moreover, even if the flouring coating 41 becomes damaged, a new fluorine coating 41 can be provided by replacing the ring spacer 40, and hence the function of preventing the heat transfer sheet 38 from becoming attached to the heat transfer sheet contact surface 40a can be easily maintained.

Although in the above described embodiments, the focus ring mounting surface 22a and the heat transfer sheet contact surface 40a which the heat transfer sheet 38 contacts are coated with fluorine because the heat transfer sheet 38 is made of conductive silicon rubber, that materials that coat these surfaces are preferably changed according to the constituent material of the heat transfer sheet 38. Specifically, a coating may be comprised of a material having a molecule bond structure into which molecules constituting the heat transfer sheet 38 cannot easily enter.

Further, the substrates subjected to the plasma processing according to the above described embodiments are not limited to being semiconductor wafers, but rather may instead be any of various glass substrates used in LCDs (Liquid Crystal Displays), FPDs (Flat Panel Displays), or the like.

### EXAMPLES

Next, the present invention will be concretely described.

### Example 1

First, in the substrate processing apparatus 42, the fluorine coating 41 is formed by FG-5010S135 produced by Fluoro Technology Co., Ltd, and the thickness thereof was set to 100 μm.

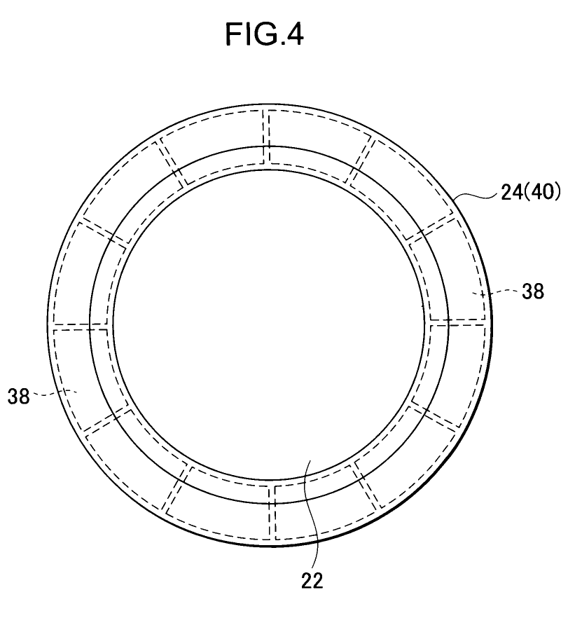

Next, as shown in FIG. 4, twelve heat transfer sheets 38 were disposed between the ring spacer 40 and the focus ring 24 and at regular intervals along the circumference of the focus ring 24.

In the substrate processing apparatus 42, etching processing was carried out on an oxide film of a wafer W five times, and then the focus ring 24 was removed from the susceptor 12 (focus ring removal test). At this time, the number of heat transfer sheets 38 still attached to the ring spacer 40 was checked, and whether each heat transfer sheet 38 was broken or not was determined. In removing the focus ring 24 from the susceptor 12, a spatula is inserted between the focus ring 24 and the electrostatic chuck 22. The number of times the spatula was inserted between the focus ring 24 and the electrostatic chuck 22 was also measured. In general, reducing the number of times of inserting the spatula between the focus ring 24 and the electrostatic chuck 22 means that it becomes easy to remove the focus ring 24 from the susceptor 12.

The results were then summarized in Table 1 below. It should be noted that the above described focus ring removal test was conducted three times.

### Comparative Example 1

First, in the substrate processing apparatus 42, without forming the fluorine coating 41 on the heat transfer sheet contact surface 40a of the ring spacer 40, the heat transfer sheet 38 was made to directly contact the heat transfer sheet contact surface 40a.

Next, as is the case with the example 1, heat transfer sheets 38 were disposed at regular intervals along the circumference of the focus ring 24, etching processing was carried out on an oxide film of a wafer W five times, and the number of heat transfer sheets 38 still attached to the ring spacer 40 and the like were checked. The results were summarized in Table 1 below.

TABLE 1

| | | Number of | Whether | |
|---|---|---|---|---|
| | | remaining | any heat | |
| | | heat | transfer | Number of |
| | Number of | transfer | sheet is | spatula |
| | tests | sheets | broken | insertions |
| Example 1 | First | 0/12 | No | 1 |
| | Second | 4/12 | No | 2 |
| | Third | 2/12 | No | 3 |
| Comparative | | 12/12 | Yes | 3 |
| example 1 | | | | |

As is apparent from the results shown in Table 1, it was found that by forming the fluorine coating 41 on the heat transfer sheet contact surface 40a, the heat transfer sheets 38 can be prevented from becoming attached to the heat transfer sheet contact surface 40a. Also, it was inferred from the results shown in Table 1 that by forming the fluorine coating 39 on the focus ring mounting surface 22a in the substrate processing apparatus 10, the heat transfer sheet 38 can be prevented from becoming attached to the focus ring mounting surface 22a.

The present inventors also conducted the same focus ring removal test as in the example 1 using the substrate processing apparatus 42 configured in the same manner as in the example 1 except that the thickness of the fluorine coating 41 was set to 6 μm, and ascertained that the same results in the example 1 shown in Table 1 can be obtained. The present inventors thus found that the thickness of the fluorine coating 41 has only to be set to at least 6 μm so as to prevent the heat transfer sheet 38 from becoming attached to the heat transfer sheet contact surface 40a.

The present inventors then investigated the effects of the fluorine coating 41 on the etching processing.

### Example 2

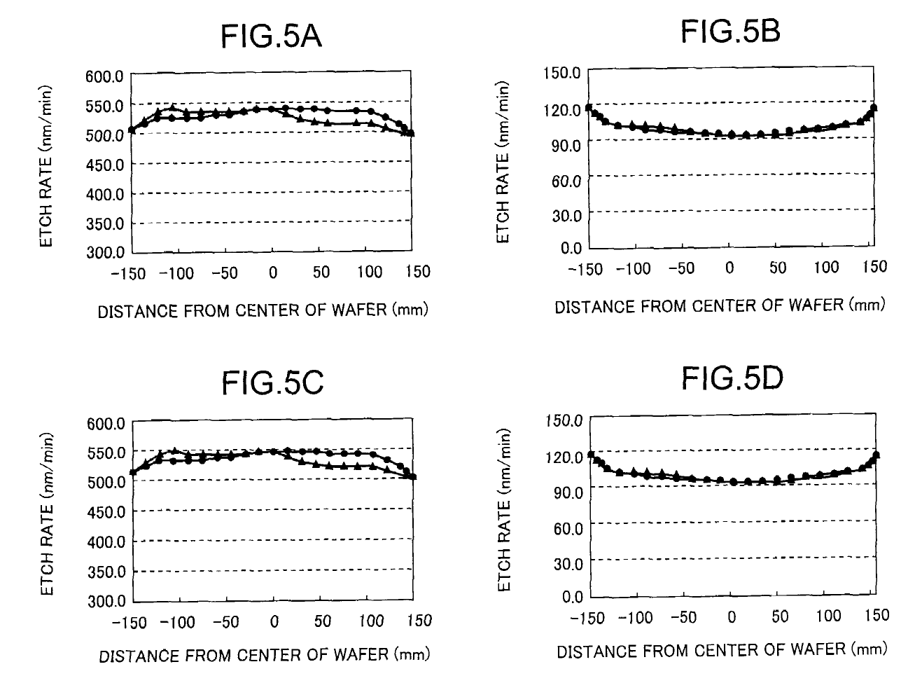

First, as is the case with the example 1, the thickness of the fluorine coating 41 was set to 100 μm in the substrate processing apparatus 42. Next, etching processing was carried out on an oxide film of a wafer W, and the etch rate in the etching processing was measured. Then, etching processing was carried out on a BARC film (antireflection film) of another wafer W, and the etch rate in the etching processing was measured. Then, the results of the etching processing on the oxide film were summarized in FIG. 5A, and the results of the etching processing on the BARC film were summarized in FIG. 5B. It should be noted that the etching of the oxide film is high-power etching, and the etching of the BARC film is lower-power etching.

### Comparative Example 2

First, as is the case with the comparative example 1, without forming the fluorine coating 41, the heat transfer sheet 38 was made to directly contact the heat transfer sheet contact surface 40a. Next, etching processing was carried out on an oxide film of a wafer W, and the etch rate in the etching processing was measured. Then, etching processing was carried out on a BARC film of another wafer W, and the etch rate in the etching processing was measured. Then, the results of the etching processing on the oxide film were summarized in FIG. 5C, and the results of the etching processing on the BARC film were summarized in FIG. 5D.

As a result of comparison between FIGS. 5A and 5C and comparison between FIGS. 5B and 5D, it was found that regarding the etching processing on the oxide film and the etching processing on the BARC film, there is no difference in etch rate between with and without the fluorine coating 41. It was thus found that insofar as the thickness of the fluorine coating 41 is set to 100 μm or less, the thermal resistance of the fluorine coating 41 is so small as to be negligible and hardly affects the etching processing.

### Comparative Example 3

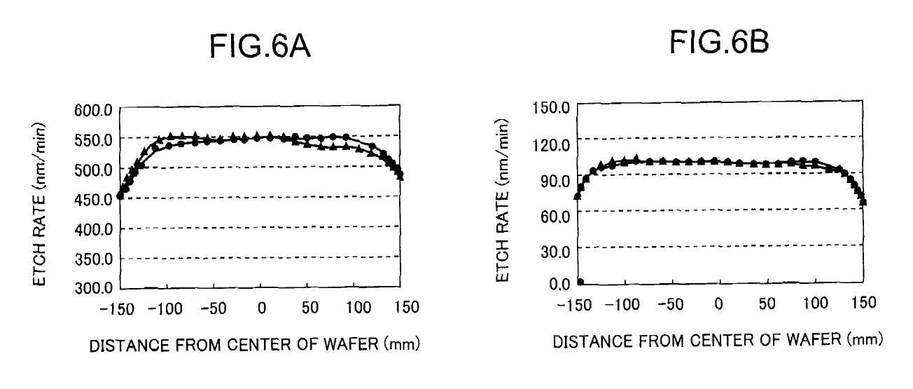

First, as is the case with the example 1, the thickness of the fluorine coating 41 was set to 100 μm in the substrate processing apparatus 42, but the heat transfer sheet 38 was not provided between the ring spacer 40 and the focus ring 24. Next, etching processing was carried out on an oxide film of a wafer W, and the etch rate in the etching processing was measured. Then, etching processing was carried out on a BARC film of another wafer W, and the etch rate in the etching processing was measured. Then, the results of the etching processing on the oxide film were summarized in FIG. 6A, and the results of the etching processing on the BARC film were summarized in FIG. 6B.

As a result of comparison between FIGS. 5A and 6A and comparison between FIGS. 5B and 6B, it was found that regarding the etching processing on the oxide film and the etching processing on the BARC film, the etch rate, in particular, the distribution thereof varies according to the presence or absence of the heat transfer sheet 38. It was inferred that this is because the temperature of the focus ring 24 varies according to the presence or absence of the heat transfer sheet 38, and the temperature distribution of a wafer W varies with the temperature change, and as a result, the distribution of etch rate varies.

What is claimed is:

1. A substrate processing apparatus comprising:
a housing chamber that houses a substrate;
a substrate mounting stage that is disposed in said housing chamber and on which the substrate is mounted; and
a focus ring that surrounds a peripheral portion of the mounted substrate,
wherein said substrate mounting stage has a focus ring mounting surface on which said focus ring is mounted,
a heat transfer sheet is interposed between said focus ring and the focus ring mounting surface, and
a fluorine coating is formed on the focus ring mounting surface.

2. A substrate processing apparatus as claimed in claim 1, wherein a thickness of the fluorine coating is not less than 3 μm and not more than 100 μm.

3. A substrate processing apparatus comprising:
a housing chamber that houses a substrate;
a substrate mounting stage that is disposed in said housing chamber and on which the substrate is mounted; and
an annular member,
wherein said substrate mounting stage has a focus ring mounting surface on which said focus ring is mounted,
a heat transfer sheet is interposed between said focus ring and the focus ring mounting surface, and
said annular member is interposed between the heat transfer sheet and the focus ring mounting surface and disposed concentrically with said focus ring and has a heat transfer sheet contact surface that contacts the heat transfer sheet, and a fluorine coating is formed on the heat transfer sheet contact surface.

4. A substrate mounting stage on which a substrate and a focus ring are mounted in a substrate processing apparatus that has a housing chamber that houses the substrate, and the focus ring that surrounds a peripheral portion of the substrate housed in the housing chamber, comprising:
a focus ring mounting surface on which the focus ring is mounted,
wherein a heat transfer sheet is interposed between the focus ring and the focus ring mounting surface, and
a fluorine coating is formed on the focus ring mounting surface.

5. A substrate mounting stage on which a substrate and a focus ring are mounted in a substrate processing apparatus that has a housing chamber that houses the substrate, and the focus ring that surrounds a peripheral portion of the substrate housed in the housing chamber, comprising:
a focus ring mounting surface on which the focus ring is mounted,
wherein a heat transfer sheet is interposed between the focus ring and the focus ring mounting surface,
an annular member disposed concentrically with said focus ring is interposed between the heat transfer sheet and the focus ring mounting surface, and
the annular member has a heat transfer sheet contact surface that contacts the heat transfer sheet, and a fluorine coating is formed on the heat transfer sheet contact surface.
